(19) United States
(12) Patent Application Publication
(10) Pub. No.: US 2008/0124915 A1
(43) Pub. Date: May 29, 2008

(54) Method for manufacturing semiconductor device

(75) Inventor: Keiichi Yamaguchi, Anpachi-Gun (JP)

Correspondence Address: OLIFF & BERRIDGE, PLC, P.O. BOX 320850, ALEXANDRIA, VA, 22320-4850, US

(73) Assignee: SANYO ELECTRIC CO., LTD., MORIGUCHI-SHI (JP)

(21) Appl. No.: 11/808,884

(22) Filed: Jun. 13, 2007

(30) Foreign Application Priority Data
Jun. 14, 2006 (JP) 2006-164314

(51) Int. Cl. H01L 21/768

(52) U.S. Cl. 438/637; 438/683; 257/E21.577; 257/E21.586; 257/E21.593

(57) ABSTRACT

An insulation film having an open part in which a silicon part is exposed at a bottom surface is formed on a silicon substrate for forming a semiconductor device. Titanium is deposited to form a titanium film on the bottom surface and side wall surfaces of the contact hole. The silicon substrate and the titanium film are reacted with each other by a first annealing process to form a titanium silicide film on the bottom surface. After the titanium film that remains on the side wall surfaces of the contact hole is removed, a hydrogen annealing process is performed. This hydrogen annealing reduces the density of the interface level in the interface between the silicon substrate, the gate insulation film on the substrate surface, or the like, and improves the characteristics of the semiconductor device. After the hydrogen annealing, tungsten is deposited in the remaining space of the contact hole to form a tungsten plug. According to this manufacturing method, since a barrier metal composed of a titanium film is not formed on the bottom surface and side wall surfaces of the contact hole, trapping of hydrogen by titanium is suppressed, and hydrogen annealing is effectively performed.

### CROSS-REFERENCE TO RELATED APPLICATION

The priority application number JP2006-164314 upon which this patent application is based is hereby incorporated by the reference.

### BACKGROUND OF THE INVENTION

1. Field of the Invention

The present invention relates to a method for manufacturing a semiconductor device, and particularly relates to a method for forming a structure that uses tungsten as a material for a contact with a portion composed of silicon.

2. Description of the Related Art

In a semiconductor device formed using a silicon substrate, the dimensions of wiring or contacts must be further reduced as the degree of integration is increased. A tungsten plug in which tungsten (W) as a contact material is embedded in a contact hole is known as a structure that is effective for this miniaturization. A structure in which a contact for a silicon substrate or polysilicon wiring is formed by a tungsten plug is also used in CCD (Charge Coupled Device) image sensors as resolution becomes progressively higher and the chip size smaller.

FIG. 1 is a schematic sectional view showing a conventional contact structure that uses tungsten as the contact material. This diagram shows the contact structures for each of the silicon substrate 2 and the gate electrode 6. A silicon oxide film (SiO₂) 4 is formed as a gate insulation film on the silicon substrate 2, and polysilicon or another conductive material is deposited on the surface of the SiO₂ film 4. The film of the conductive material is patterned by a photolithography technique to form a gate electrode 6. A silicon oxide film (SiO₂) 8 is then deposited as an interlayer insulation film. Contact holes 10 are formed in the SiO₂ film 8. Tungsten 16 is embedded in the contact holes 10 to form tungsten plugs. In the commonly known method for forming a tungsten plug, the internal surfaces of the contact holes 10 are first coated with a titanium (Ti) film 12 by sputtering or the like, and a titanium nitride (TiN) film 14 is then deposited by sputtering or CVD (Chemical Vapor Deposition) on the Ti film 12. The tungsten plugs are then formed by depositing tungsten 16 inside the contact holes 10 by CVD. In the sputtering process for forming the TiN film 14, the sputtering device causes a Ti target to react in a nitrogen gas atmosphere to form TiN on the surface of the target, the target is sputtered in argon gas (Ar) or the like, and the TiN on the target surface is deposited on the surface of the semiconductor device.

A CCD image sensor is manufactured by a process that includes a step for introducing an impurity into the silicon substrate 2 and forming a charge transfer channel region, a channel separation region, a floating diffusion (FD) region, and other diffusion layers; a step for layering an insulation film and a polysilicon layer on the silicon substrate 2; a step for forming a contact for the polysilicon layer or the diffusion layers and forming metal wiring; and other steps. Annealing in a hydrogen atmosphere or other gas atmosphere is performed in a relatively late stage of the manufacturing process. In this annealing process, dangling bonds occurring at the interface between the silicon substrate 2 and the gate insulation film 4 in the prior manufacturing process can be terminated by hydrogen that is present in the gas atmosphere or hydrogen that is generated from the deposited film. In an analog device that handles charges generated by light or the like, such as a CCD image sensor or CMOS image sensor, the effects of energy level on device performance due to the presence of dangling bonds in the interface between the silicon substrate and the gate insulation film are more significant than in memory devices, logic circuits, and other digital devices. The annealing process is therefore an important step for CCD image sensors and other analog devices.

As described above, the contacts have the Ti film 12 and the TiN film 14 as barrier metals in the conventional tungsten plug structure. These films have already been formed prior to the abovementioned annealing step. Ti is known to have hydrogen trapping properties. Therefore, in the conventional tungsten plug structure, the Ti film 12 or the Ti deposited in the TiN film 14 without being nitrided during formation of the TiN traps hydrogen that is in the atmosphere or that diffuses from the deposited film to the interface between the silicon substrate 2 and the gate insulation film 4, and drawbacks occur in that the dangling bonds in the interface between the silicon substrate 2 and the gate insulation film 4 are not adequately terminated by hydrogen. The annealing is therefore ineffective, and there are adverse effects on the device performance in a semiconductor device that handles charges generated by light or the like, such as a CCD image sensor or CMOS image sensor. In a CCD image sensor, for example, the effects of titanium on the wiring portion that lines the transfer electrodes of the imaging portion can cause defects whereby dark currents increase in a photoreceptor pixel or a transfer portion.

### SUMMARY OF THE INVENTION

The present invention provides a manufacturing method in which annealing is effectively performed during the manufacture of a semiconductor device that uses tungsten as the contact material.

The method for manufacturing a semiconductor device according to the present invention comprises an insulation film formation step for forming an insulation film on a silicon part, wherein the insulation film has an open part in which the silicon part is exposed at a bottom surface; a titanium deposition step for depositing titanium and forming a titanium film on at least the bottom surface of the open part after the insulation film formation step; a silicide formation step for reacting the silicon part with the titanium film by a first annealing process and forming a titanium silicide film on the bottom surface after the titanium deposition step; a titanium film removal step for removing the remaining titanium film after the silicide formation step; a tungsten plug formation step for depositing tungsten that is electrically connected to the silicon part via the titanium silicide film in the open part after the titanium film removal step; and an interface level density reduction step for performing a second annealing process after at least the titanium film removal step is performed.

### BRIEF DESCRIPTION OF THE DRAWINGS

FIG. 1 is a schematic sectional view showing the structure of a conventional contact;

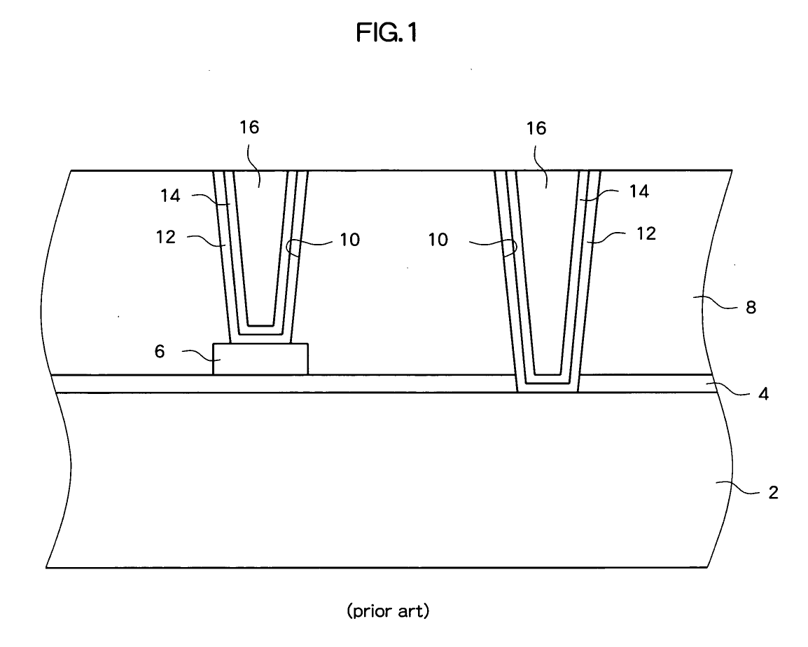

FIG. 2 is a schematic plan view showing the overall structure of a CCD image sensor as an embodiment of the present invention;

FIG. 3 is a schematic plan view showing the overall arrangement of the polysilicon layers and the contacts in the CCD image sensor as an embodiment of the present invention;

FIG. 4 is a schematic diagram showing the cross-sectional structure of the imaging portion and the storage portion of the CCD image sensor as an embodiment of the present invention;

FIG. 5 is a schematic diagram showing the cross-sectional structure of the horizontal transfer portion and the output portion of the CCD image sensor as an embodiment of the present invention;

FIGS. 6A through 6E are schematic sectional views showing the main steps for the imaging portion of the CCD imaging sensor as an embodiment of the present invention; and

FIGS. 7A through 7E are schematic sectional views showing the main steps for the imaging portion of the CCD imaging sensor as an embodiment of the present invention.

### DESCRIPTION OF THE PREFERRED EMBODIMENTS

Embodiments of the present invention will be described hereinafter based on the drawings.

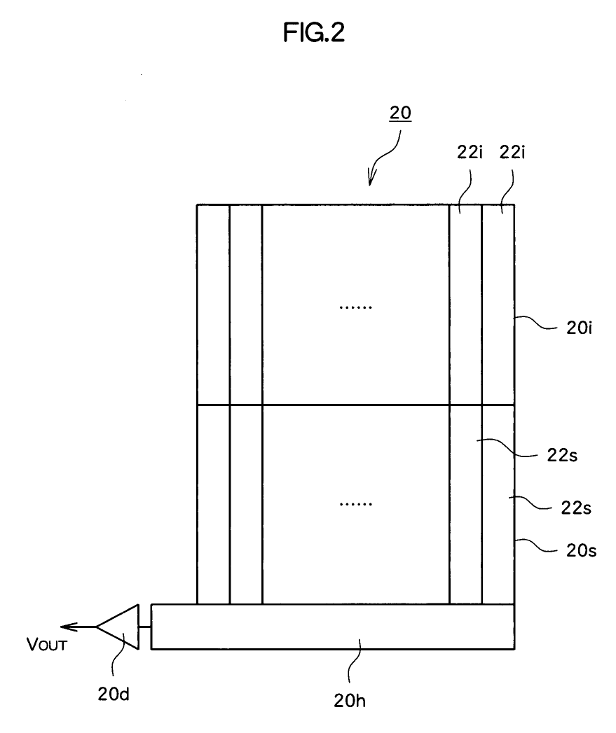

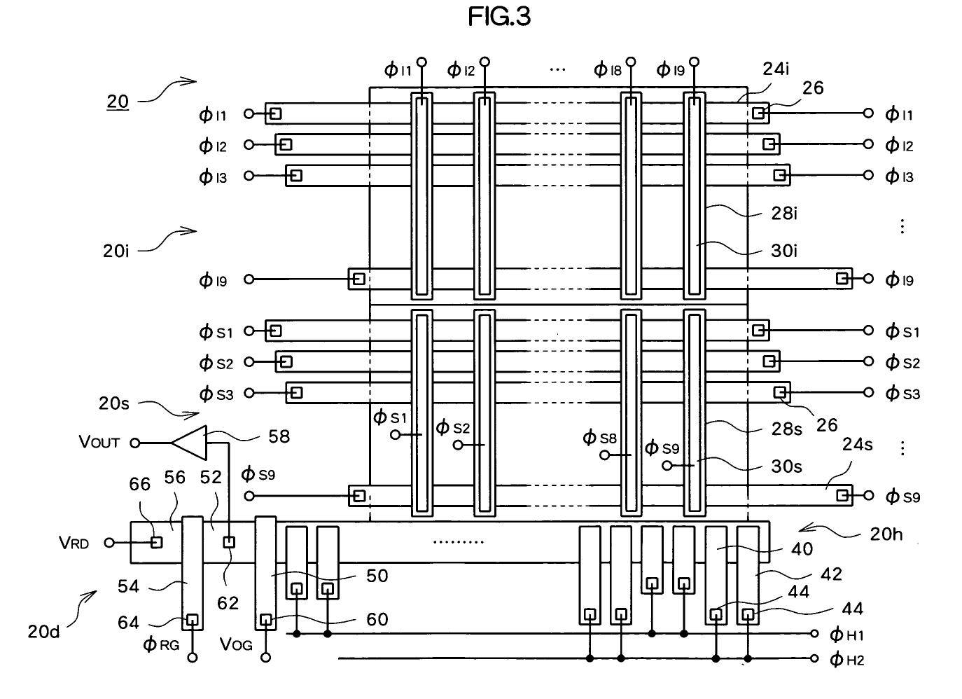

FIG. 2 is a schematic plan view showing the overall structure of a CCD image sensor as an embodiment of the present invention. FIG. 3 is a schematic plan view showing the overall arrangement of the polysilicon layers and the contacts in the CCD image sensor as an embodiment of the present invention.

The CCD image sensor 20 has a frame transfer architecture, and is provided with an imaging portion 20i, a storage portion 20s, a horizontal transfer portion 20h, and an output portion 20d formed on the surface of a semiconductor substrate.

The imaging portion 20i is composed of a plurality of vertical shift registers (vertical CCD shift registers) 22i arranged in the row direction (horizontal direction). The storage portion 20s is composed of a plurality of vertical shift registers 22s that correspond one-to-one to the plurality of vertical shift registers 22i of the imaging portion 20i. The vertical shift registers 22s are arranged in the row direction and have charge transfer channels that are connected to the corresponding vertical shift registers 22i.

The bits of the vertical shift registers 22i of the imaging portion 20i form a light-receiving pixel, and signal charges are generated and accumulated in accordance with incident light. Signal charges accumulated during an exposure period in the imaging portion 20i are vertically transferred at high speed to the storage portion 20s through a frame transfer operation. The storage portion 20s is covered by a light-shielding film to prevent generating charges due to incident light, and the signal charges that are frame-transferred from the imaging portion 20i are therefore substantially maintained in an unmodified state.

The vertical shift registers 22i, 22s are provided with a plurality of vertical transfer electrodes 24i, 24s, which are arranged parallel to each other in the column direction so as to extend in the row direction on the substrate. The vertical transfer electrodes 24i, 24s are composed of polysilicon and are formed using a first polysilicon layer (1^{st} poly-Si layer) and a second polysilicon layer (2^{nd} poly-Si layer), for example. Contacts 26 are provided to both ends of the vertical transfer electrodes 24i, 24s or to predetermined intersection points between the electrodes 24i, 24s and lined wiring 28. The vertical transfer electrodes 24i, 24s are connected to clock signal lines via the contacts 26 and the lined wiring 28. The vertical transfer electrodes 24i, 24s control the potential of a charge transfer channel formed on the semiconductor substrate, and the control is performed according to multi-phase transfer clocks φ_{I}, φ_{S} applied from a drive circuit via clock signal lines. For example, a configuration is adopted in the CCD image sensor 20 whereby nine transfer electrodes that are arranged in any three consecutive bits of the vertical shift registers 22i, 22s can be driven independently of each other so as to enable image capture in which the number of pixels is compressed in a movie shooting mode or preview mode. In corresponding fashion, nine clock signal lines are provided to the imaging portion 20i and the storage portion 20s, respectively, and every ninth vertical transfer electrodes 24i, 24s arranged in the column direction is connected to the same clock signal line.

The drive circuit controls the transfer clocks φ_{I1} through φ_{I9} that are fed to the clock signal lines of the imaging portion 20i, controls the transfer clocks φ_{S1} through φ_{S9} that are fed to the clock signal lines of the storage portion 20s, and switches between still image shooting, movie image shooting, and preview. For example, the still image shooting involves performing standard driving, which is three-phase driving in which the three transfer electrodes of each bit are each in a different phase. The moving image shooting and preview involve performing pixel reduction driving in which a frame is transferred after signal charges are additively synthesized for every three consecutive pixels in the column direction of the imaging portion 20i.

The vertical transfer electrodes are relatively long in the horizontal direction and, what is more, the width (dimension in the vertical direction) generally decreases as the pixel density is increased. The waveform of the transfer clock applied to the vertical transfer electrodes therefore degrades closer to the center, and decreased transfer efficiency and other problems can occur. In order to prevent these problems, lined wiring is formed on the channel separation region between vertical shift registers that are adjacent to each other in the row direction. A plurality of units of lined wiring is arranged in the row direction, and the lined wiring is connected via the contacts 26 to the vertical transfer electrodes which are traversing under the lined wiring and correspond to a specific phase. Since the vertical transfer electrodes are connected to the lined wiring at intermediate positions along the row direction, and are fed the transfer clock from the drive circuit via the lined wiring, differences in the waveform of the transfer clock according to the position in the row direction can be suppressed.

The CCD image sensor 20 has the lined wiring to the imaging portion 20i and to the storage portion 20s. The lined wiring has a structure in which polysilicon wiring 28 and tungsten wiring 30 are layered with each other. Polysilicon wiring 28i is arranged in the column direction over the imaging portion 20i in which the vertical transfer electrodes 24i are formed. For example, the polysilicon wiring 28i is formed using a third polysilicon layer (3^{rd} poly-Si layer). Tungsten wiring 30i is embedded as a tungsten plug in a trench formed in a silicon oxide film that is layered on the 3^{rd} poly-Si layer. This trench extends in the column direction on the polysilicon wiring 28i and penetrates to the surface of the polysilicon wiring 28i. The trench and the embedding of the tungsten wiring 30i are formed by a process described hereinafter, and other contacts are also formed by the same process. Lined wiring composed of mutually layered polysilicon wiring 28s and tungsten wiring 30s is also formed in the storage portion 20s in the same manner as the lined wiring of the imaging portion 20i.

The horizontal transfer portion 20h is composed of a horizontal CCD shift register, and each bit thereof is connected to an output terminal of the charge transfer channels of the vertical shift registers 22s. For example, a pair of horizontal transfer electrodes 40, 42 is provided to each bit. The horizontal transfer electrode 40 is composed of a 1^{st} poly-Si layer, and the horizontal transfer electrode 42 is composed of a 2^{nd} poly-Si layer, for example. A barrier region whose channel potential is shallower than the horizontal transfer electrode 40 is formed under the horizontal transfer electrode 42, and a channel potential gradient towards the output portion 20d is thereby formed under each horizontal transfer electrode. The horizontal transfer electrodes 40, 42 in the pair are connected to a shared clock signal line via a contact 44. Each electrode pair controls the potential of the charge transfer channel formed on the semiconductor substrate in accordance with multi-phase transfer clocks φ_{H} applied from the drive circuit. For example, the horizontal transfer portion 20h is driven by two-phase horizontal transfer clocks, φ_{H1}, φ_{H2}.

The output portion 20d includes an output gate electrode (OG) 50, a floating diffusion layer (FD) 52, a reset gate electrode (RG) 54, a reset drain (RD) 56, and an output amplifier 58. The OG 50 is connected to a signal line that feeds a predetermined voltage V_{OG} via a contact 60. The FD 52 comprises an electrically isolated capacity. Signal charges are transferred from the horizontal transfer portion 20h to the FD 52 through a charge transfer channel under the OG 50, and the FD 52 is set to a potential that corresponds to the quantity of the signal charges. The potential of the FD 52 is brought out to a signal line via a contact 62 and inputted to the output amplifier 58 as a voltage signal. The output amplifier 58 amplifies the inputted voltage signal and outputs the output signal V_{OUT} of the CCD image sensor 20. The RG 54 is connected to a signal line for feeding a clock signal ORG via a contact 64. The RD 56 is connected to a signal line via a contact 66, and the signal line is connected to a predetermined positive voltage source V_{RD}. The FD 52, the RG 54, and the RD 56 form a MOS transistor, and when φ_{RG} causes an ON state to occur, the signal charges accumulated in the FD 52 are discharged to the positive voltage source V_{RD} via the RD 56.

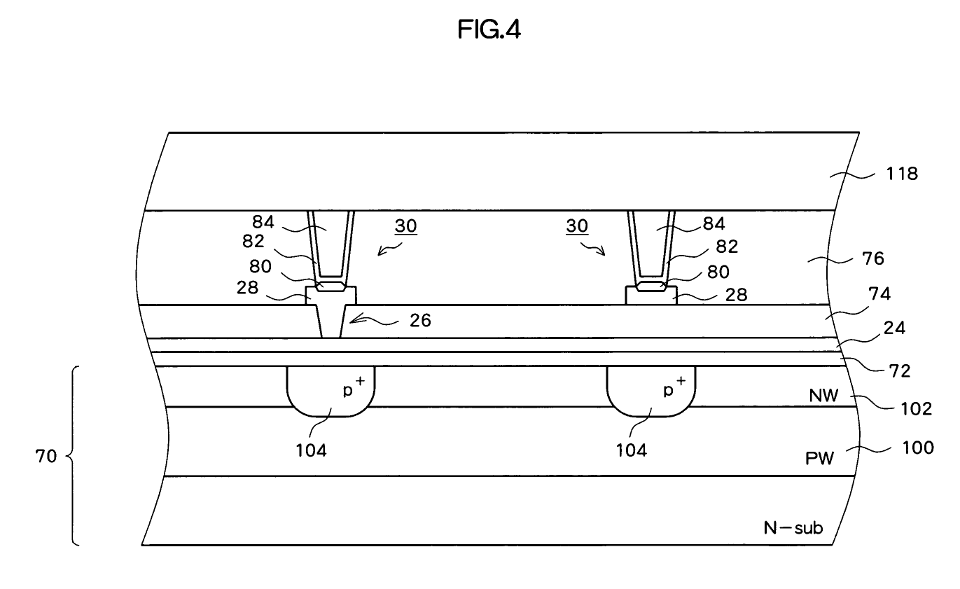

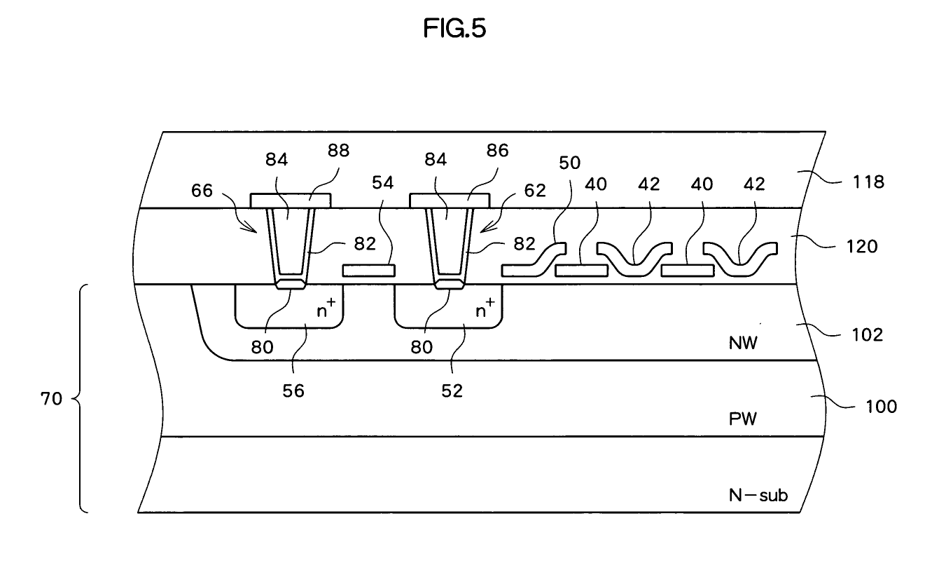

FIG. 4 is a schematic diagram showing the cross-sectional structure of the imaging portion and the storage portion in the horizontal direction, and FIG. 5 is a schematic diagram showing the cross-sectional structure of the horizontal transfer portion and the output portion in the horizontal direction. FIG. 4 is a sectional view showing the silicon substrate 70, the gate insulation film 72, the vertical transfer electrode 24, the polysilicon wiring 28 that forms the lower layer of the lined wiring, the contact 26 for connecting the polysilicon wiring 28 and the vertical transfer electrode 24, and the tungsten wiring 30 that forms the upper layer of the lined wiring. FIG. 5 is a sectional view showing the horizontal transfer electrodes 40, 42, the FD 52, the RD 56, and the contacts 62, 66 for the FD 52 and the RD 56. The contact trench for forming the tungsten wiring 30 in FIG. 4 is formed by using a photolithography technique to pattern a silicon oxide film 76 that is deposited as an insulation film after the polysilicon wiring 28 is formed. At this time, contact holes or trenches are also formed for providing the contacts 44, 60, 62, 64, 66 for the above-mentioned horizontal transfer electrodes 40, 42, the OG 50, the FD 52, the RG 54, and the RD 56. Including these contacts, the contacts of the CCD image sensor 20 are formed using tungsten plugs. The lined wiring of the imaging portion will be used as an example to describe the structure of the contacts. The lower layer part of the lined wiring is formed by the polysilicon wiring 28. The tungsten wiring 30 that constitutes the upper layer part of the lined wiring is composed of Ti silicide film 80 that contacts the polysilicon wiring 28; TiN film 82 that covers the upper surfaces of the Ti silicide film 80 and the side wall surfaces of the contact hole; and tungsten 84 that is embedded in the contact trench covered by the TiN film 82.

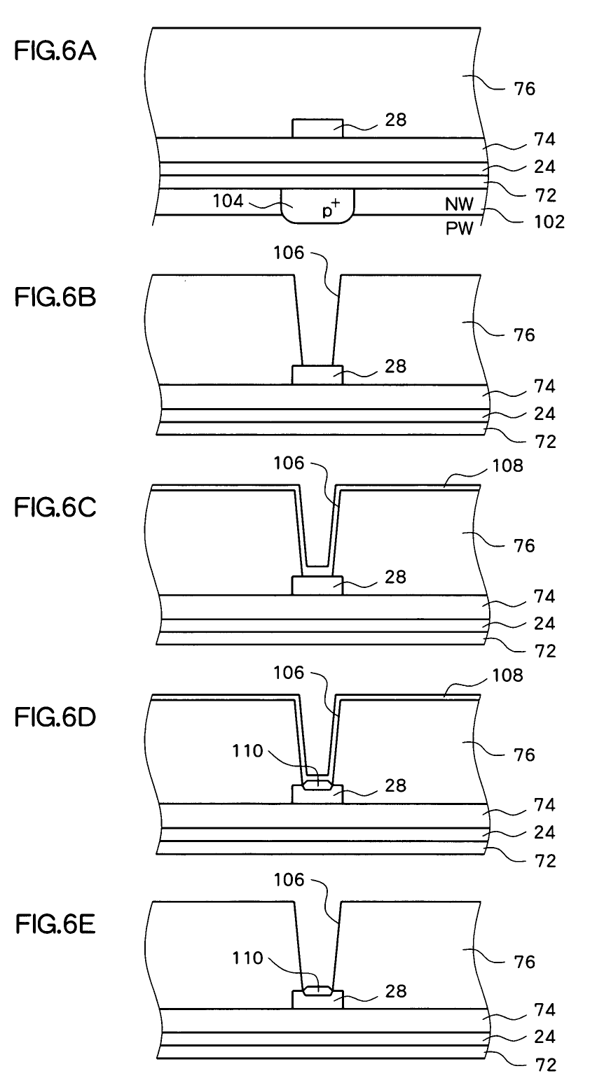

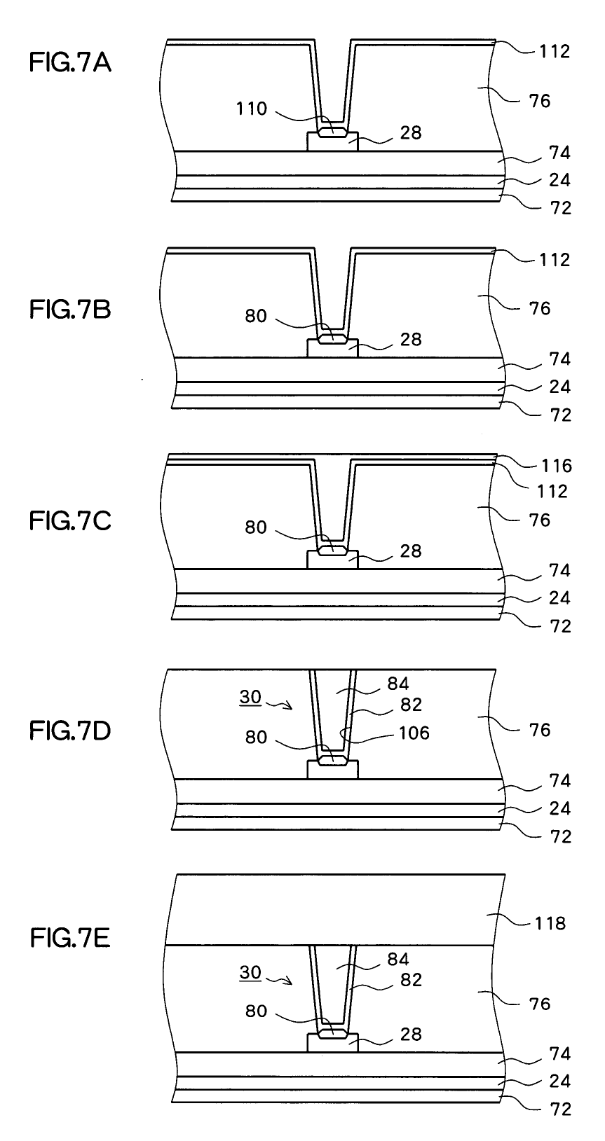

The method for manufacturing the CCD image sensor 20 will next be described with reference to FIGS. 6A through 6E, and FIGS. 7A through 7E. FIGS. 6A through 6E, and FIGS. 7A through 7E are schematic sectional views that depict the imaging portion and show the main steps in the method for manufacturing the CCD imaging sensor 20 of the present invention.

The CCD image sensor 20 is formed on the principal surface of the silicon substrate 70. A silicon semiconductor substrate (N-sub) that includes n-type impurities, for example, is used as the silicon substrate 70. N-type impurities or p-type impurities are ion-implanted into the surface of the silicon substrate 70, and thermal diffusion or the like is performed to form various types of diffusion layers. Ion implantation can be performed selectively in the desired regions of the surface of the silicon substrate 70 using an ion implantation mask or the like formed by a photolithography technique. For example, p-type impurities are ion-implanted into substantially the entire CCD image sensor 20, and thermal diffusion is then performed to form a p-well (PW) 100. An n-well (NW) 102 that does not reach as deeply as the p-well 100 is formed in the charge transfer channel region or other region of each CCD shift register. P⁺ regions 104 are also formed in a channel separation region or other region between the charge transfer channel regions. First through third polysilicon layers are formed in sequence on the silicon substrate 70. A gate insulation film 72, and interlayer insulation films 74, 76 formed from silicon oxide films (SiO₂), for example, are formed between the polysilicon layers and the silicon substrate 70, or between the polysilicon films in order to provide insulation. FIG. 6A is a sectional view showing the vicinity of the imaging portion at the stage in which the lower layer part of the lined wiring is formed by the 3^{rd} poly-Si layer that is the final polysilicon layer, and the interlayer insulation film 76 is deposited thereon.

In the state shown in FIG. 6A, a photoresist is applied to the surface of the silicon oxide film 76, and the photoresist is patterned to form an etching mask having an opening in the position in which the tungsten wiring 30 that constitutes the upper layer part of the lined wiring is to be formed. Etching is performed using this etching mask, and an open part for forming a trench 106 into which tungsten is embedded is formed in the silicon oxide film 76. Open parts for forming the contact holes or trenches of other contacts 62 and the like are also simultaneously formed at this time. FIG. 6B shows a state in which the etching mask on the surface of the silicon oxide film 76 is removed after etching of the silicon oxide film 76 is completed.

The trench 106 penetrates through the silicon oxide film 76, and the polysilicon wiring 28 that constitutes the lower layer part of the lined wiring is exposed on the bottom surface of the trench 106. A Ti film 108 is vapor-deposited by sputtering on the surface of the silicon oxide film 76 in which the trench 106 is formed. In this step, the side wall surfaces of the trench 106 and the exposed silicon substrate at the bottom of the trench 106 are coated by the Ti film 108 (FIG. 6C).

A Ti silicide film 110 is formed in self-aligning fashion on the surface of the polysilicon wiring 28 exposed on the bottom surface of the trench 106 through a SALICIDE (self-aligned-silicide) process using the Ti film 108. The Ti silicide film 110 is formed by a process of annealing in a nitrogen atmosphere. FIG. 6D shows a state in which the Ti silicide film 110 is formed on the bottom surface of the trench 106. This annealing can be performed through RTA (Rapid Thermal Annealing), for example. When RTA is used, heat treatment can be completed in a short time, and it is possible to prevent such phenomena as unnecessary spreading of diffusion layers that are already formed in the silicon substrate 70.

The portion of the Ti film 108 that was not changed to silicide in the abovementioned annealing process is removed. Specifically, the Ti film 108 remaining on the side wall surfaces of the trench 106 and other portions not in contact with the polysilicon is removed while the Ti silicide film 110 remains on the bottom surface of the trench 106 (FIG. 6E). The Ti film 108 that was not changed to silicide can include TiN generated through reaction with nitrogen in the atmosphere. This TiN is also removed in the process of removing the Ti film 108. For example, the Ti film 108 and TiN can be removed from the surface of the silicon oxide film 76 by a washing process using ammonia peroxide. The ammonia peroxide is a mixture of ammonia (NH₄OH), hydrogen peroxide (H₂O₂), and water (H₂O).

After the Ti film 108 is removed, a TiN film 112 is formed by sputtering. The TiN film 112 is obtained by reacting the surface of a Ti target with nitrogen gas to form TiN, and depositing the TiN. In this step, a layered structure of the Ti silicide film 110 and the TiN film 112 is formed on the bottom surface in the trench 106, and the side wall surfaces are also coated by the TiN film 112 (FIG. 7A).

In this state, annealing is performed again in a nitrogen atmosphere by RTA, for example. A phase transition can be brought about in the crystal structure of the Ti silicide film 110 by this annealing process. Two stable phases, referred to as a C49 phase and a C54 phase, are present in the Ti silicide. The specific resistance of the C49 phase is 60 to 70 μΩcm, and the specific resistance of the C54 phase is 15 to 20 μΩcm. Specifically, the C49 phase has higher resistance than the C54 phase, and the C54 phase has low resistance. The Ti silicide film 110 in FIG. 6 formed by the first annealing process has the C49 phase. The annealing process in this step causes a transition of the C49-phase Ti silicide film 110 to the C54-phase Ti silicide film 80 by heat treatment (FIG. 7B). The contact resistance of the tungsten and the polysilicon is thereby reduced. The annealing conditions for the phase transition of the Ti silicide film vary according to the impurity concentration in the Ti silicide film and the thickness of the Ti silicide film, but an example of the annealing conditions is RTA for about ten seconds at 900° C.

In this step, the nitrogen in the atmosphere can change the yet-unreacted Ti in the TiN film 112 to TiN.

A tungsten film 116 is deposited by CVD in the state in which the TiN film 112 is formed. For example, tungsten is formed and deposited by the reaction between WF₆ gas and silane (SiH₄) gas to form the tungsten film 116. The remaining space in the trench 106 is filled by the tungsten film 116 (FIG. 7C).

The deposited layer on the upper surface of the silicon oxide film 76 is then removed by etching back or CMP (Chemical Mechanical Polishing). A tungsten plug 84 embedded in the trench 106 is thereby formed, and the tungsten wiring 30 that forms the upper layer part of the lined wiring is completed (FIG. 7D).

An interlayer insulation film is also layered on the surface of the silicon oxide film 76. A microlens array or color filters having color transmission characteristics that correspond to each light-receiving pixel are arranged on the imaging portion 20i. The structures formed after W embedding are indicated as an upper layer 118 in FIG. 7E.

In the process of forming the upper layer 118, for example, prior to adding the color filters, annealing for modifying the surface of the silicon substrate is performed. This annealing process is a step for reducing the interface level density at the interface between the silicon substrate 70 and the gate insulation film 72, and is performed by heating in an atmosphere that includes hydrogen. Since the tungsten wiring 30 of the CCD image sensor 20 has the above-described tungsten plug structure that does not include a Ti film on the side walls, hydrogen is not trapped in this structure, and the concentration of hydrogen that is present in the atmosphere during annealing, or the concentration of hydrogen that is generated from the deposited film, can be kept in the vicinity of the interface between the silicon substrate 70 and the gate insulation film 72. The interface level density between the silicon substrate 70 and the gate insulation film 72 can thus be effectively reduced by this annealing process.

The tungsten plug structure makes it possible to get the flatness of the aluminum (Al) wiring in the contact portion, and is effective for miniaturization of devices in that minute aluminum wiring can be satisfactorily formed, and resistance to electromigration is enhanced. The tungsten plug structure is also not limited to image sensors, and has also come to be used in memory devices and other semiconductor devices. According to the contact manufacturing method of the present invention, in addition to the common advantages obtained from the tungsten plug structure in the past, it is also possible to get the effects of the annealing process for producing the reduced interface level that is particularly necessary in analog devices and the like as described above, and the contact resistance can be reduced.

The tungsten wiring 30 that constitutes the lined wiring for the imaging portion was used above as an example to describe the contact manufacturing method of the present invention, but the other contacts 44, 60, 62, 64, 66, and other portions in which tungsten was embedded can also be formed by the same process, and the same effects can be obtained.

For example, FIG. 5 shows the contact 62 for connecting the FD 52 and the aluminum wiring 86, and the contact 66 for connecting the RD 56 and the aluminum wiring 88. First formed in the contacts 62, 66 are contact holes that penetrate the gate insulation film 72 on the silicon substrate 70 and that penetrate an insulation layer 120 composed of the interlayer insulation films 74, 76. Ti silicide films 80 are then formed on the bottom surfaces of the contact holes, and TiN films 82 that cover the upper surfaces of the Ti silicide films 80 and the side wall surfaces of the contact holes are formed, after which tungsten plugs 84 are embedded in the remaining spaces in the contact holes.

Forming the contact structure connected to the silicon substrate in the same process as the tungsten wiring 30 described above creates a structure that suppresses the trapping of hydrogen in the vicinity of the contacts, and makes it possible to efficiently perform the annealing process for reducing the interface level of the interface between the gate insulation film and the silicon substrate of the imaging portion 20i and the storage portion 20s. As a result, dark currents that occur in light-receiving pixels are reduced in the imaging portion 20i. Signal charges are stored for a relatively long time in the storage portion 20s. The present invention makes it possible to reduce dark current components that are accumulated in the storage period of the signal charges of each bit of the vertical shift registers of the storage portion 20s.

Forming a Ti silicide film between the silicon substrate and the tungsten plug enables the silicon substrate and the wiring disposed in upper layers to be connected with lower resistance. The power supply is thereby stabilized, and signal degradation during signal amplification is also suppressed.

A phase transition to lower resistance is preferably brought about in the crystal structure of the Ti silicide film 110 by the second annealing process described above, but this phase transition is not necessarily required. Even when no phase transition is brought about, the tungsten wiring 30 of the CCD image sensor 20 has the tungsten plug structure described above in which no Ti film is included on the side walls, and there is therefore no trapping of hydrogen. The effects whereby the interface level density between the silicon substrate 70 and the gate insulation film 72 is reduced are thus satisfactorily obtained in the subsequent annealing process.

The present embodiment was described with reference to a CCD image sensor 20, but the present invention can also be applied to other semiconductor devices that include manufacturing processes aimed at terminating hydrogen at dangling bonds. For example, the present invention can be applied to CMOS image sensors, thin-film transistors, or solar cells.

As described above, the method for manufacturing a semiconductor device according to the present invention comprises an insulation film formation step for forming an insulation film on a silicon part, wherein the insulation film has an open part in which the silicon part is exposed at a bottom surface; a Ti deposition step for depositing Ti and forming a Ti film on at least the bottom surface of the open part after the insulation film formation step; a silicide formation step for reacting the silicon part with the Ti film by a first annealing process and forming a Ti silicide film on the bottom surface after the Ti deposition step; a Ti film removal step for removing the remaining Ti film after the silicide formation step; a tungsten plug formation step for depositing tungsten that is electrically connected to the silicon part via the Ti silicide film in the open part after the Ti film removal step; and an interface level density reduction step for performing a second annealing process after at least the Ti film removal step is performed.

According to the present invention, a Ti film is formed before tungsten is embedded in the open part. The Ti film is used for forming a Ti silicide film. Specifically, the Ti film forms a Ti silicide film through an annealing process and in self-aligning fashion on the bottom surface of the open part in which electrical contact is to be established between the tungsten electrode and silicon parts such as the silicon substrate or the gate electrode. Since the Ti film that remains unreacted outside the area of the bottom surface is removed in the subsequent step, hydrogen that is in the atmosphere or is generated from the deposited film is prevented from being trapped by Ti in the subsequent annealing process.

In the embodiment described above, a manufacturing method was described that includes a TiN deposition step for depositing a TiN film on the Ti silicide film formed on the bottom surface of the open part, subsequent to the Ti film removal step; and a phase transition step for performing a third annealing process in an atmosphere that includes nitrogen to cause the Ti silicide film to change from a high-resistance phase to a low-resistance phase, prior to the tungsten plug formation step.

In the above-described manufacturing method, which relates to a semiconductor device in which a surface of a silicon substrate has a region for generating signal charges in accordance with incident light, or a region for storing the signal charges, the second annealing process may be performed under conditions in which an interface level density between the silicon substrate and an insulation film formed on a surface of the silicon substrate can be reduced.

In the above-described manufacturing method, which relates to a semiconductor device that includes a charge coupled device in which a charge transfer region is formed on a silicon substrate, the second annealing process may be performed under conditions in which an interface level density between the silicon substrate and a gate insulation film can be reduced. For example, in a semiconductor device that is provided a charge coupled device, the silicon part is silicon wiring of the charge coupled device, or is a diffusion layer in the silicon substrate.

Annealing of a semiconductor device is performed effectively by the present invention. Specifically, hydrogen in the annealing atmosphere, hydrogen in the deposited film, or the like efficiently reaches the interface between the silicon substrate in the semiconductor device, the gate insulation film on the substrate surface, or the like. The density of the interface level caused by dangling bonds in the interface between the silicon substrate and the gate insulation film or the like is thereby reduced, and improved characteristics of the semiconductor device are anticipated. A contact structure having low contact resistance is achieved by the interposition of a Ti silicide film between the tungsten wiring and the silicon substrate part or the silicon gate electrode part. An even greater reduction in contact resistance is anticipated particularly through the phase transition of the crystal structure of the Ti silicide film by subjecting the Ti silicide film formed on the contacting part of the contacts to annealing following formation of the TiN film. A reduced interface level density in the interface portion between the silicon substrate and the gate insulation film achieved through the annealing process is effective for improving the device characteristics of analog devices such as image sensors.

What is claimed is:

1. A method for manufacturing a semiconductor device, comprising:
an insulation film formation step for forming an insulation film on a silicon part, wherein the insulation film has an open part in which the silicon part is exposed at a bottom surface;
a titanium deposition step for depositing titanium and forming a titanium film on at least the bottom surface of the open part after the insulation film formation step;
a silicide formation step for reacting the silicon part with the titanium film by a first annealing process and forming a titanium silicide film on the bottom surface after the titanium deposition step;
a titanium film removal step for removing the remaining titanium film after the silicide formation step;
a tungsten plug formation step for depositing tungsten that is electrically connected to the silicon part via the titanium silicide film in the open part after the titanium film removal step; and
an interface level density reduction step for performing a second annealing process after at least the titanium film removal step is performed.

2. The method for manufacturing a semiconductor device according to claim 1, wherein the manufacturing method comprises:
a titanium nitride deposition step for depositing a titanium nitride film on the titanium silicide film formed on the bottom surface of the open part, subsequent to the titanium film removal step and prior to the tungsten plug formation step; and
a phase transition step for performing a third annealing process in an atmosphere that includes nitrogen to cause the titanium silicide film to change from a high-resistance phase to a low-resistance phase, subsequent to the titanium nitride deposition step and prior to the tungsten plug formation step.

3. The method for manufacturing a semiconductor device according to claim 1, wherein
a surface of a silicon substrate of the semiconductor device has a region for generating signal charges in accordance with incident light, or a region for storing the signal charges; and
the second annealing process is performed under conditions in which an interface level density between the silicon substrate and an insulation film formed on a surface of the silicon substrate can be reduced.

4. The method for manufacturing a semiconductor device according to claim 1, wherein
the semiconductor device is provided a charge coupled device in which a charge transfer region is formed on a silicon substrate; and
the second annealing process is performed under conditions in which an interface level density between the silicon substrate and a gate insulation film can be reduced.

5. The method for manufacturing a semiconductor device according to claim 4, wherein the silicon part is silicon wiring of the charge coupled device, or is a diffusion layer in the silicon substrate.
